(19) United States
(12) Patent Application Publication
(10) Pub. No.: US 2023/0128298 A1
(43) Pub. Date: Apr. 27, 2023

(54) Electro-Static Discharge Protection Structure and High-Voltage Integrated Circuit

(71) Applicant: Shanghai Huali Microelectronics Corporation, Shanghai (CN)

(72) Inventor: Tianzhi Zhu, Shanghai (CN)

(73) Assignee: Shanghai Huali Microelectronics Corporation, Shanghai (CN)

(21) Appl. No.: 17/891,413

(22) Filed: Aug. 19, 2022

(30) Foreign Application Priority Data
Oct. 26, 2021 (CN) 202111244706.9

(51) Int. Cl. H01L 27/02

(52) U.S. Cl. CPC H01L 27/0274; H01L 27/0296; H01L 27/0292

(57) ABSTRACT

The present application discloses an electro-static discharge protection structure, which includes an N-well and a P-well formed in a substrate. Upper parts and middle parts of the N-well and the P-well are isolated by shallow trench isolation (STI), and lower parts adjoin. The upper part of the N-well to form an N-well P-type heavily doped region adjacent to the STI. The upper part of the N-well to form an N-well N-type heavily doped region far away from the STI. The upper part of the P-well forms a P-well P-type heavily doped region adjacent to the STI. The N-well P-type heavily doped region and the N-well N-type heavily doped region are short-circuited to form an anode of the electro-static discharge protection structure. The P-well P-type heavily doped region is used as a cathode of the electro-static discharge protection structure. The present application can realize no snapback effect.

### CROSS-REFERENCES TO RELATED APPLICATIONS

This application claims the priority to Chinese Patent Application No. 202111244706.9, filed on Oct. 26, 2021, the disclosure of which is incorporated herein by reference in its entirety.

### TECHNICAL FIELD

The present application relates to a semiconductor circuit structure, in particular to an electro-static discharge protection structure and a high-voltage integrated circuit.

### BACKGROUND

The electro-static discharge protection design of the high-voltage circuit has always been a technical problem, because it constitutes the core of the high-voltage circuit. High-voltage devices (for example, LDMOS (Laterally Diffused Metal Oxide Semiconductor)) are not suitable for electro-static discharge protection design as ordinary low-voltage devices, because the snapback effect curve of the high-voltage devices shows poor characteristics. From the LDMOS snapback effect curve of the conventional high-voltage device illustrated in FIG. 1, it can be concluded that: 1) the holding voltage (Vh) is too low, which is often much lower than the working voltage of the high-voltage circuit, and the latch-up effect is easily caused during the normal operation of the high-voltage circuit; 2) the secondary breakdown current (thermal breakdown current It2) is too low, which is caused by localized current crowding due to the structural characteristics of the device when LDMOS discharges Electro-Static Discharge (ESD) current.

Therefore, when implementing the electro-static discharge protection design of the high-voltage circuit, the industry often adopts two ideas: 1) adjusting the structure of a high-voltage device used for an electro-static discharge protection module, and optimizing its snapback effect curve to make it suitable for the electro-static discharge protection design, but it is often difficult to practice because of the structural characteristics of the high-voltage device itself; 2) a certain number of low-voltage electro-static discharge protection devices are connected in series to form an electro-static discharge protection circuit that can withstand high voltage. Because the characteristics of low-voltage electro-static discharge protection devices are relatively easy to adjust and control, the industry, especially integrated circuit design companies, often prefer to use a certain number of low-voltage electro-static discharge protection devices connected in series.

Because of the need of the electro-static discharge protection design window of the high-voltage circuit, there are certain requirements for the snapback effect characteristics of low-voltage electro-static discharge protection devices. It is often required that the smaller the snapback effect window is, the better. It is better to have no snapback effect, that is, the holding voltage and trigger voltage of the snapback effect are basically the same. Low-voltage PMOS device is a common electro-static discharge protection device without a snapback effect due to the small current gain of a parasitic PNP triode when the snapback effect occurs. The schematic diagram of the specific device structure is as illustrated in FIG. 2.

However, the disadvantage of the low-voltage PMOS device is that the secondary breakdown current (It2) of its snapback effect is relatively small, and the trigger voltage Vt1 of the low-voltage PMOS device is relatively small, because the trigger voltage Vt1 of the low-voltage PMOS device is mainly determined by its drain breakdown voltage (Bvdss), so there will be more series connection stages required in the design of multi-stage series connection for high-voltage electro-static discharge protection. For example, taking a 32V high-voltage process platform as an example, the trigger voltage Vt1 and holding voltage Vh of the low-voltage PMOS device of the high-voltage process platform are about 10.5V, as illustrated in FIG. 3. It often requires four stages of series connection of the low-voltage PMOS device to realize the electro-static discharge protection of the 32V high-voltage port.

### BRIEF SUMMARY

The technical problem to be solved by the present application is to provide an electro-static discharge protection structure, which can realize no snapback effect, is easy to obtain higher trigger voltage and holding voltage, and has higher secondary breakdown current. When applied to the electro-static discharge protection design of the high-voltage port, it can reduce the number of series connection stages required for multi-stage series connection and the layout area of the single-stage protection unit.

In order to solve the technical problem, the electro-static discharge protection structure provided by the present application includes an N-well 20 and a P-well 30 formed in a substrate 10;

upper parts and middle parts of the N-well 20 and the P-well 30 are isolated by STI (Shallow Trench Isolation) 40;

lower parts of the N-well 20 and the P-well 30 adjoin;

P-type heavily doping ions are implanted to a position, adjacent to the STI 40, of the upper part of the N-well 20 to form an N-well P-type heavily doped region 24;

N-type heavily doping ions are implanted to a position, far away from the STI 40, of the upper part of the N-well 20 to form an N-well N-type heavily doped region 22;

P-type heavily doping ions are implanted to a position, adjacent to the STI 40, of the upper part of the P-well 30 to form a P-well P-type heavily doped region 26;

the N-well P-type heavily doped region 24 and the N-well N-type heavily doped region 22 are short-circuited to form an anode of the electro-static discharge protection structure;

the P-well P-type heavily doped region 26 is used as a cathode of the electro-static discharge protection structure.

Further, the N-type ion doping concentration of the N-well N-type heavily doped region 22 is higher than 10 times the N-type ion doping concentration of the N-well 20.

Further, the P-type ion doping concentration of the N-well P-type heavily doped region 24 and the P-well P-type heavily doped region 26 higher than 10 times the P-type ion doping concentration of the P-well 30.

Further, the substrate 10 is P-type doped;

the doping concentration of the substrate 10 is lower than the doping concentration of the P-well.

Further, the space a from the N-well P-type heavily doped region 24 to a boundary where the N-well 20 and the P-well 30 adjoin ranges from 0.2 um to 2 um;

the space b from the P-well P-type heavily doped region 26 to a boundary where the P-well 30 and the N-well 20 adjoin ranges from 0.2 um to 2 um.

The present application further provides a high-voltage integrated circuit adopting the electro-static discharge protection structure. A high-voltage IO of the high-voltage integrated circuit is connected with an internal circuit;

N electro-static discharge protection structures connected with the high-voltage IO of the high-voltage integrated circuit in series are connected with the ground, and N is a positive integer.

Further, the high-voltage IO of the high-voltage integrated circuit is connected with a working power supply Vdd through an ESD device.

Further, M electro-static discharge protection structures are connected in series between the working power supply and the ground, and M is a positive integer.

Since the trigger voltage (Vt1) of the electro-static discharge protection structure provided by the present application is determined by the reverse breakdown voltage of N-well 20/P-well 30, higher trigger voltage (Vt1) can be obtained by adjusting the reverse breakdown voltage, and it is easy to obtain higher trigger voltage (Vt1). In addition, since the Space between Anode and Cathode (SAC) is short, it is conducive to reducing the total resistance of the ESD conduction path. Electro-Static Discharge (ESD) current sequentially flows through the N-well P-type heavily doped region 24, the lower part of the N-well 20, the lower part of the P-well 30 and the P-well P heavily doped region 26. The ESD current goes deep into the substrate 10. Since the substrate 10 is a relatively good conductor of heat, going deep into the substrate 10 is conducive to heat dissipation in the ESD conduction state. Thus, referring to FIG. 6, the electro-static discharge protection structure can realize the characteristics of no snapback effect. Its trigger voltage (Vt1) and holding voltage (Vh) are about 20V and the secondary breakdown current (It2) is high. Its ideal working secondary breakdown current (It2) can reach more than 5 mA/um. Since the electro-static discharge protection structure is easy to obtain higher trigger voltage (Vt1) and can have higher secondary breakdown current (It2), taking the electro-static discharge protection design of a 32V high-voltage port of a 32V high-voltage process platform as an example, the electro-static discharge protection structure provided by the present application can be applied after two stages are connected in series. Therefore, when the electro-static discharge protection structure is applied to the electro-static discharge protection design of the high-voltage port of the high-voltage integrated circuit, it can reduce the number of series connection stages required for multi-stage series connection and the layout area of the single-stage protection unit.

### BRIEF DESCRIPTION OF THE DRAWINGS

In order to more clearly describe the technical solution of the present application, the drawings required for the present application will be briefly introduced below. It is obvious that the drawings in the following description are only some embodiments of the present application. Those skilled in the art may obtain other drawings based on these drawings without contributing any inventive labor.

FIG. 1 illustrates an LDMOS snapback effect curve of a conventional high-voltage device.

FIG. 2 illustrates a schematic diagram of a structure of a traditional PMOS electro-static discharge protection device.

FIG. 3 illustrates a multi-stage series connection snapback effect curve of a PMOS device of a 32V high-voltage process platform.

FIG. 4 illustrates a schematic diagram of an electro-static discharge protection structure according to an embodiment of the present application.

FIG. 5 illustrates a relationship between reverse breakdown voltage and a/b of an electro-static discharge protection structure according to an embodiment of the present application.

FIG. 6 illustrates a snapback effect curve of an electro-static discharge protection structure according to an embodiment of the present application.

FIG. 7 illustrates a schematic diagram of a high-voltage integrated circuit adopting an electro-static discharge protection structure according to the present application.

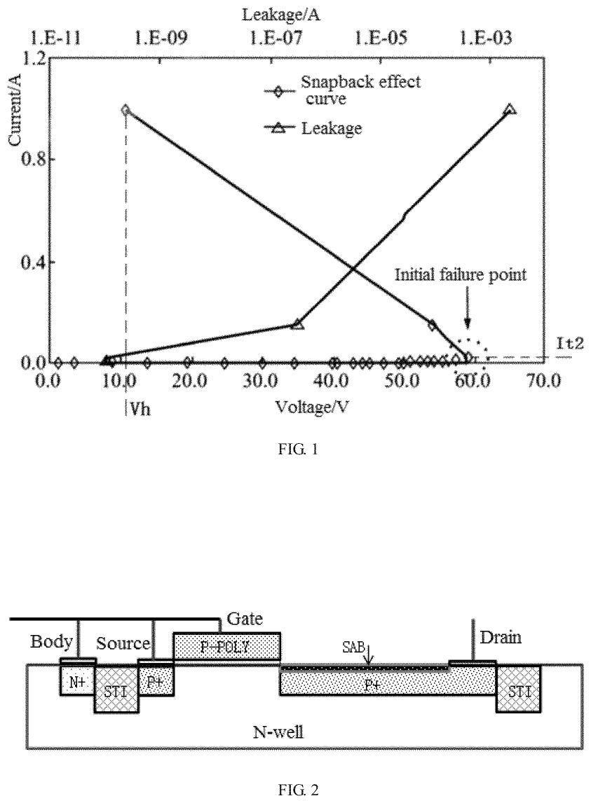

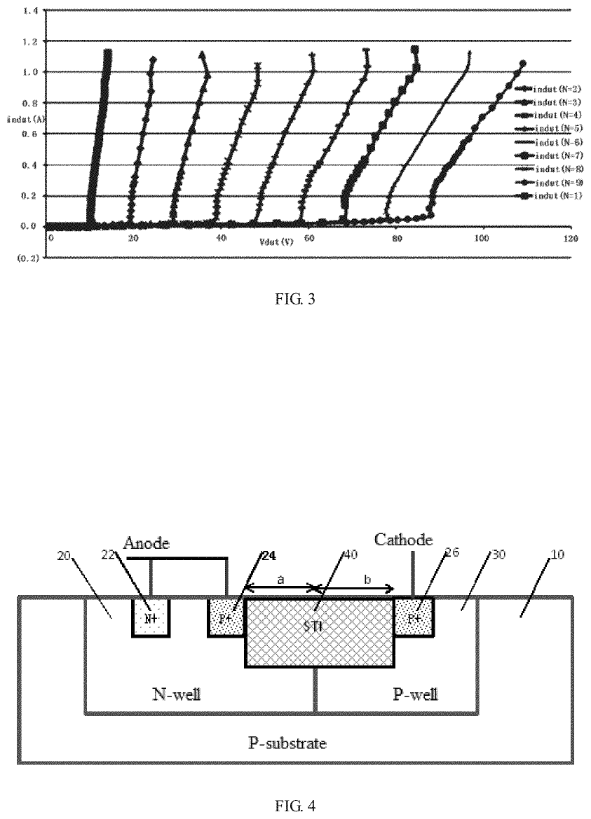

### DETAILED DESCRIPTION OF THE APPLICATOIN

The technical solution of the present application will be clearly and completely described below with reference to the drawings. Obviously, the described embodiments are part of the embodiments of the present application, not all of them. Based on the embodiments of the present application, all other embodiments obtained by those skilled in the art without contributing any inventive labor still fall within the scope of protection of the present application.

### Embodiment 1

Referring to FIG. 4, the electro-static discharge protection structure includes an N-well 20 and a P-well 30 formed in a substrate 10;

upper parts and middle parts of the N-well 20 and the P-well 30 are isolated by STI (Shallow Trench Isolation) 40;

lower parts of the N-well 20 and the P-well 30 adjoin;

P-type heavily doping ions are implanted to a position, adjacent to the STI 40, of the upper part of the N-well 20 to form an N-well P-type heavily doped region 24;

N-type heavily doping ions are implanted to a position, far away from the STI 40, of the upper part of the N-well 20 to form an N-well N-type heavily doped region 22;

P-type heavily doping ions are implanted to a position, adjacent to the STI 40, of the upper part of the P-well 30 to form a P-well P-type heavily doped region 26;

the N-well P-type heavily doped region 24 and the N-well N-type heavily doped region 22 are short-circuited to form an anode of the electro-static discharge protection structure;

the P-well P-type heavily doped region 26 is used as a cathode of the electro-static discharge protection structure.

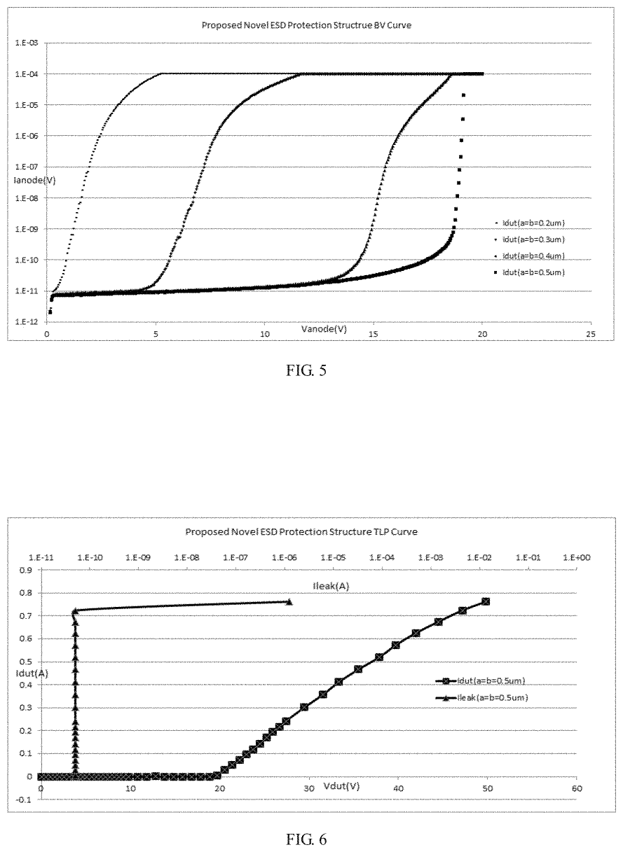

Since the trigger voltage (Vt1) of the electro-static discharge protection structure according to embodiment 1 is determined by the reverse breakdown voltage of N-well 20/P-well 30, higher trigger voltage (Vt1) can be obtained by adjusting the reverse breakdown voltage, and it is easy to obtain higher trigger voltage (Vt1). In addition, since the Space between Anode and Cathode (SAC) is short, it is conducive to reducing the total resistance of the ESD conduction path. Electro-Static Discharge (ESD) current sequentially flows through the N-well P-type heavily doped region 24, the lower part of the N-well 20, the lower part of the P-well 30 and the P-well P heavily doped region 26. The ESD current goes deep into the substrate 10. Since the substrate 10 is a relatively good conductor of heat, going deep into the substrate 10 is conducive to heat dissipation in the ESD conduction state. Thus, referring to FIG. 6, the electro-static discharge protection structure has higher secondary breakdown current (It2) and its ideal working secondary breakdown current (It2) can reach more than 5 mA/um. Since the electro-static discharge protection structure can realize no snapback effect, it is easy to obtain higher trigger voltage (Vt1) and holding voltage (Vh), and it can have higher secondary breakdown current (It2). Therefore, when the electro-static discharge protection structure is applied to the electro-static discharge protection design of the high-voltage port of the high-voltage integrated circuit, it can reduce the number of series connection stages required for multi-stage series connection and the layout area of the single-stage protection unit. It is very suitable for the electro-static discharge protection design of the high-voltage integrated circuit.

### Embodiment 2

Based on the electro-static discharge protection structure according to embodiment 1, the N-type ion doping concentration of the N-well N-type heavily doped region 22 is higher than 10 times the N-type ion doping concentration of the N-well 20.

Further, the P-type ion doping concentration of the N-well P-type heavily doped region 24 and the P-well P-type heavily doped region 26 is higher than 10 times the P-type ion doping concentration of the P-well 30.

Further, the substrate 10 is P-type doped;

the doping concentration of the substrate 10 is lower than the doping concentration of the P-well.

### Embodiment 3

Based on the electro-static discharge protection structure according to embodiment 1, the space a from the N-well P-type heavily doped region 24 to the boundary where the N-well 20 and the P-well 30 adjoin ranges from 0.2 um to 2 um;

the space b from the P-well P-type heavily doped region 26 to the boundary where the P-well 30 and the N-well 20 adjoin ranges from 0.2 um to 2 um.

The trigger voltage (Vt1) of the electro-static discharge protection structure according to embodiment 3 is affected by parameters a and b within a certain range. Referring to FIG. 5 and FIG. 6, in a process platform, when the values of a and b reach 0.5 um, the reverse breakdown voltage reaches 19.1V, while the trigger voltage (Vt1) and holding voltage (Vh) reach about 20V. Therefore, the electro-static discharge protection structure can be applied to the electro-static discharge protection design of the 32V high-voltage port through two-stage series connection.

### Embodiment 4

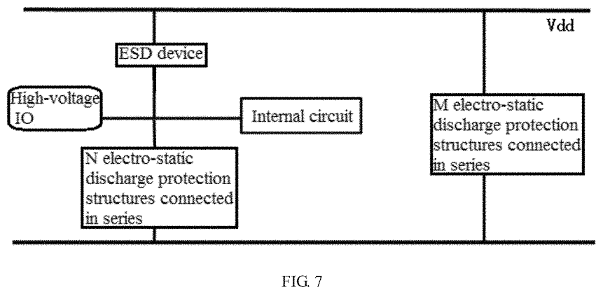

A high-voltage integrated circuit adopting the electro-static discharge protection structure according to embodiment 1 or embodiment 2 is provided. Referring to FIG. 7, a high-voltage IO (input/output) of the high-voltage integrated circuit is connected with an internal circuit;

N electro-static discharge protection structures connected with the high-voltage IO of the high-voltage integrated circuit in series are connected with the ground Vss, and N is a positive integer.

Further, the high-voltage IO of the high-voltage integrated circuit is connected with a working power supply Vdd through an ESD device.

Further, M electro-static discharge protection structures are connected in series between the working power supply Vdd and the ground Vss, and M is a positive integer.

What are described above are only preferred embodiments of the present application, which, however, are not used to limit the present application. Any modification, equivalent replacement, improvement and the like made within the essence and principle of the present application shall be included in the scope of protection of the present application.

What is claimed is:

1. An electro-static discharge protection structure, wherein the electro-static discharge protection structure comprises an N-well and a P-well formed in a substrate;
upper parts and middle parts of the N-well and the P-well are isolated by shallow trench isolation (STI);
lower parts of the N-well and the P-well adjoin;
P-type heavily doping ions are implanted to a position, adjacent to the STI, of the upper part of the N-well to form an N-well P-type heavily doped region;
N-type heavily doping ions are implanted to a position, far away from the STI, of the upper part of the N-well to form an N-well N-type heavily doped region;
P-type heavily doping ions are implanted to a position, adjacent to the STI, of the upper part of the P-well to form a P-well P-type heavily doped region;
the N-well P-type heavily doped region and the N-well N-type heavily doped region are short-circuited to form an anode of the electro-static discharge protection structure; and
the P-well P-type heavily doped region is used as a cathode of the electro-static discharge protection structure.

2. The electro-static discharge protection structure according to claim 1, wherein an N-type ion doping concentration of the N-well N-type heavily doped region is higher than 10 times an N-type ion doping concentration of the N-well.

3. The electro-static discharge protection structure according to claim 1, wherein a P-type ion doping concentration of the N-well P-type heavily doped region and the P-well P-type heavily doped region is higher than 10 times a P-type ion doping concentration of the P-well.

4. The electro-static discharge protection structure according to claim 1, wherein
the substrate is P-type doped; and
a doping concentration of the substrate is lower than a doping concentration of the P-well.

5. The electro-static discharge protection structure according to claim 1, wherein
a space from the N-well P-type heavily doped region to a boundary where the N-well and the P-well adjoin ranges from 0.2 um to 2 um; and
a space from the P-well P-type heavily doped region to the boundary where the N-well and the P-well adjoin ranges from 0.2 um to 2 um.

6. A high-voltage integrated circuit adopting the electro-static discharge protection structure according to claim 1, wherein
a high-voltage IO of the high-voltage integrated circuit is connected with an internal circuit; and
N electro-static discharge protection structures connected with the high-voltage IO of the high-voltage integrated circuit in series are connected with the ground, and N is a positive integer.

7. The high-voltage integrated circuit according to claim 6, wherein the high-voltage IO of the high-voltage integrated circuit is connected with a working power supply through an ESD device.

8. The high-voltage integrated circuit according to claim 7, wherein M electro-static discharge protection structures are connected in series between the working power supply and the ground, and M is a positive integer.
